(19) United States
(12) Patent Application Publication
(10) Pub. No.: US 2008/0011453 A1
(43) Pub. Date: Jan. 17, 2008

(54) Heat-Dissipating Device For Memory And Method For Manufacturing The Same

(76) Inventor: Robert Liang, Taoyuan Hsien (TW)

Correspondence Address: LIN & ASSOCIATES INTELLECTUAL PROPERTY, INC., P.O. BOX 2339, SARATOGA, CA, 95070-0339, US

(21) Appl. No.: 11/456,861

(22) Filed: Jul. 12, 2006

(51) Int. Cl. H05K 7/20

(52) U.S. Cl. 165/80.3; 165/185; 361/704; 257/722

(57) ABSTRACT

A heat-dissipating device for a memory and a method for manufacturing the same are disclosed herein. A primary feature is to provide an integrally manufactured heat sink. The heat sink is made of a metal plate with a certain thickness. A plurality of protrusions is provided on one side of the heat sink. Part of the other side of the heat sink is a flat surface. The flat surfaces of the two heat sinks are in contact with both sides of the memory. A clamping member holds these two heat sinks at both sides of the memory.

### BACKGROUND OF THE INVENTION

1. Field of the Invention

The present invention relates to a heat-dissipating device for a memory and a method for manufacturing the same.

2. The Prior Arts

With the increase of performance, heat has become a big issue with electronic components. Both the performance reliability and life expectancy of electronic components are inversely related to the component temperature. At present a casing of memory on the market is made of metal, which are brought into contact with the hot surface of an integrated circuit memory chip. Therefore, the metal casing transfers the memory chip's heat over a larger area enabling it to give up its heat to the surrounding air more quickly. The metal casing works as a heat-dissipating device for the conventional memory.

Referring to FIGS. 8 and 9, a conventional heat-dissipating device for a memory comprises two heat sinks A1 and A2 formed of sheet metal, which are symmetrically held in place at both sides of the memory B by a clip or a locking device, such that each chip on the memory B contacts with the heat sinks A1 and A2. Generally, the casing of the conventional memory, i.e. the heat sink, is sheet metal punched into thin grooved piece, so as to increase the surface area and enhance the strength of the sheet metal. The increase of the surface area is very limited by this way, and the thin sheet metal cannot be punched to have combs or fins thereon as conventional extruded aluminum heat sinks. Some heat sinks are made by attaching an array of metal combs or fin like protrusions onto the sheet metal with adhesive to increase the surface that are in contact with the air just like the extruded aluminum heat sink does. However, because the sheet metal and the combs or fins are not integrally manufactured, a layer of thermally conductive glue is added to bond the combs or fins onto the grooved sheet metal. It is impossible to achieve the best effect of heat transferring.

Of course, the conventional memory can utilize the extruded heat sink to dissipate the heat, but the fins on the extruded product are continuous from end to end. Before a clip is used to affix the heat sinks tight over the memory, it is necessary to remove part of the fins by machining such that a space can be provided for the clip. It makes the manufacturing process complicated and the manufacturing cost higher.

Furthermore, extrusion is a manufacturing process to create long objects of a fixed cross-section, so the fins can only be extruded as long ridges along the extruding direction. The fins cannot be extruded as ridges perpendicular to the extruding direction. The fins cannot be formed as an array of combs or raised dots either.

### SUMMARY OF THE INVENTION

A technical problem to be solved according to the present invention is that a casing of a conventional memory heat-dissipating device is formed of a punched thin sheet metal. Since punching cannot form combs or fins, they must be attached to the thin sheet metal by adhesive. Therefore, the manufacturing process becomes more complicated, and the heat transfer efficiency cannot be further improved.

Another technical problem to be solved according to the present invention is that a conventional memory heat-dissipating device is only a thin sheet metal. The mass of the heat-dissipating device also plays an important part for transferring heat from the memory. The greater the mass of the heat-dissipating device has, the more heat that can be removed and stored. The mass of the steel metal is limited, so the heat transfer efficient is poor.

Furthermore, if a conventional memory heat-dissipating device uses an extruded heat sink, it is necessary to remove part of the fins by machining such that a space can be provided for the clip. As such, the manufacturing process is more complicated, and the manufacturing cost is higher.

A primary technical feature of the present invention is to provide a thicker heat sink of metal plate manufactured integrally, wherein one side of the heat sink has a plurality of vertical protrusions and the other side is a flat surface. The flat surfaces of two heat sinks are in contact with both sides of a memory respectively. The heat sinks are held in place at both sides of the memory by a clip or locking device. The heat sinks store the heat by thicker plate and remove the heat by vertical protrusions. Thus the heat transfer efficiency is improved.

Another technical feature of the present invention is to provide the heat sink made of a copper plate, an aluminum plate, or the like, and then manufactured by forging, powder metallurgy, casting and extrusion depending on the characteristics of the materials. A plurality of protrusions is on one side of the heat sink. The protrusions may be raised dots, fins, combs, or any objects perpendicular to the metal plate.

Part of the other side of the heat sink is provided with a flat portion to be in contact with the memory. Two flat surfaces of two heat sinks are in contact with both sides of the memory, and held in place by a clip or locking device.

The aforementioned method and the heat-dissipating device of the present invention can integrally form a plurality of protrusions such as raised dots, combs, fins or the like on a thicker metal plate. It not only increases the heat-dissipating area of the heat sink, but also improves the efficiency of heat dissipating. The manufacturing process is simplified and the manufacturing cost is reduced.

The present invention will be apparent to those skilled in the art by reading the following detailed description of a preferred embodiment thereof, with reference to the attached drawings.

### BRIEF DESCRIPTION OF THE DRAWINGS

FIG. 1 is an exploded perspective view showing a first embodiment in accordance with the present invention.

FIG. 2 is an assembled perspective view showing the first embodiment in accordance with the present invention.

FIG. 3 is an exploded perspective view showing a second embodiment in accordance with the present invention.

FIG. 4 is an assembled perspective view showing the second embodiment in accordance with the present invention.

FIG. 5 is an exploded perspective view showing a third embodiment in accordance with the present invention.

FIG. 6 is an assembled perspective view showing the third embodiment in accordance with the present invention.

FIG. 7 is a cross-sectional view showing the structure of a heat sink in accordance with the present invention.

FIG. 8 is an exploded perspective view showing the assembling relationship of a conventional heat sink and a memory.

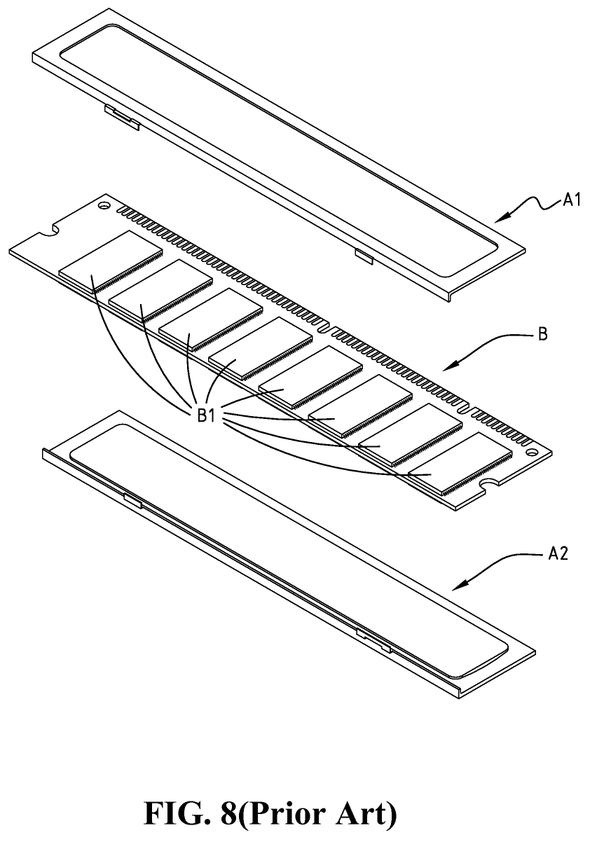

FIG. 9 is a perspective view showing a conventional heat sink and a memory after they are assembled.

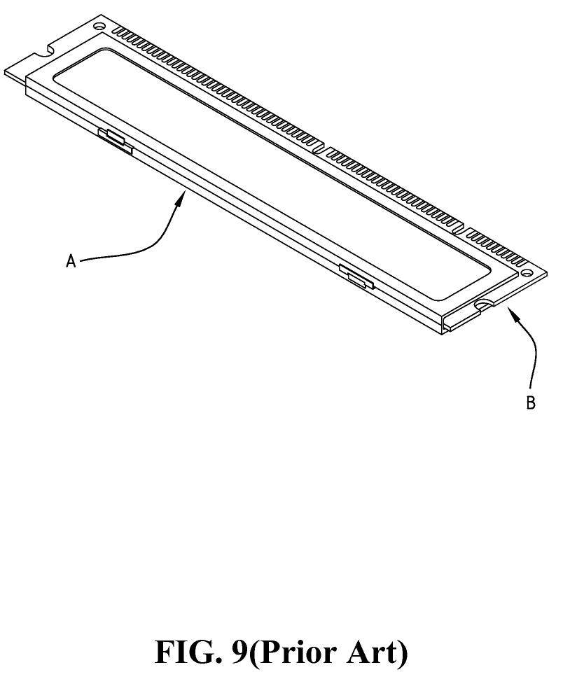

### DETAILED DESCRIPTION OF THE PREFERRED EMBODIMENT

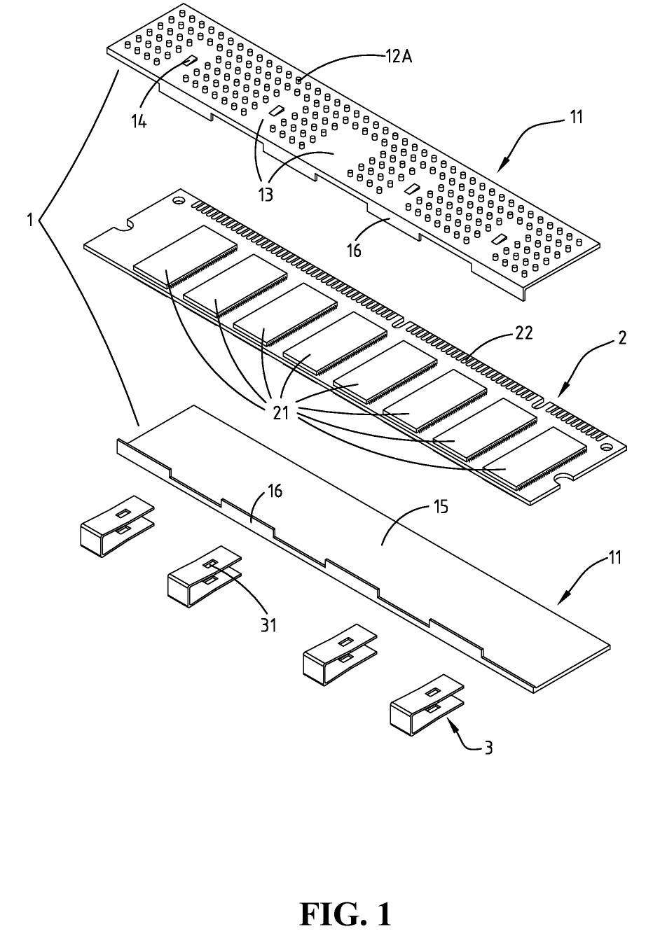

FIG. 1 is an exploded perspective view illustrating a first embodiment of a heat-dissipating device 1 used for a memory 2 according to the present invention. The heat-dissipating device 1 comprises two heat sinks 11, which is made of material with high thermal conductivity such as copper or aluminum. The heat sink 11 has a plurality of protrusions on one side. In the first embodiment, the protrusions are combs 12A. They can also be shorter in length or in spherical shapes such as raised dots (not shown). Part of the other side of the heat sink 11 is a flat surface 15. The thickness of the heat sink is not necessary to be uniform. The shape of the heat sink can be a cube, a grooved plate with raised edges or the like. A plurality of extended edges 16 extends vertically from one edge of the heat sink 11 towards the flat surface 15. The extended edges 16 of the two heat sinks 11 are staggered in such a manner that they can be fitted complementarily together. In order to fix the two heat sinks 11 together, a fixation space 13 is left between the combs 12A for mounting a clamping member 3, and has a locking wedge 14 thereon.

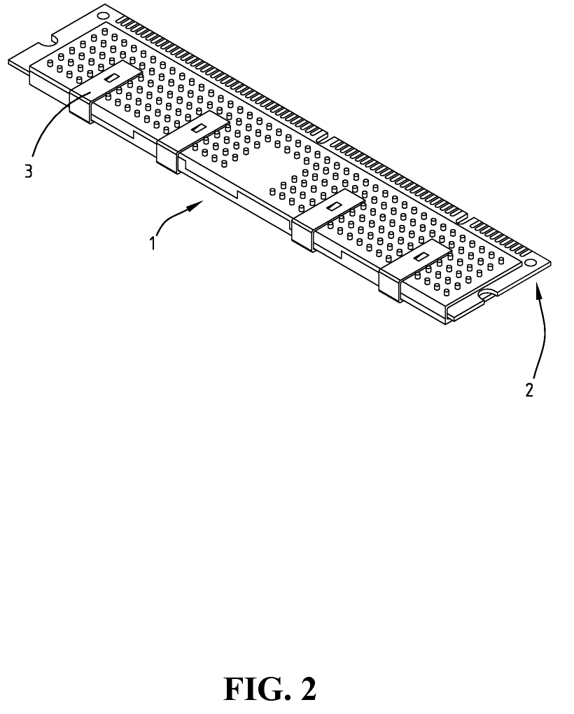

The memory 2 generally comprises a circuit board, and a plurality of chips 21 disposed on the circuit board. The package of the memory comprises a plurality of electrical connecting pins 22. The two heat sinks 11 mentioned above are symmetrically arranged at both sides of the memory 2. The flat surfaces 15 of both the heat sinks 11 are in contact with both sides of the memory 2 respectively. And then, the U-shaped clamping member 3 clamps on the fixation spaces 13 of the two heat sinks 11. The locking wedges 14 on the fixation space 13 are inserted into the locking holes 31 at both sides of the clamping member 3 to make a joint. Therefore the two heat sinks 11 are held at both sides of the memory 2. The assembled memory and heat sinks are shown in FIG. 2.

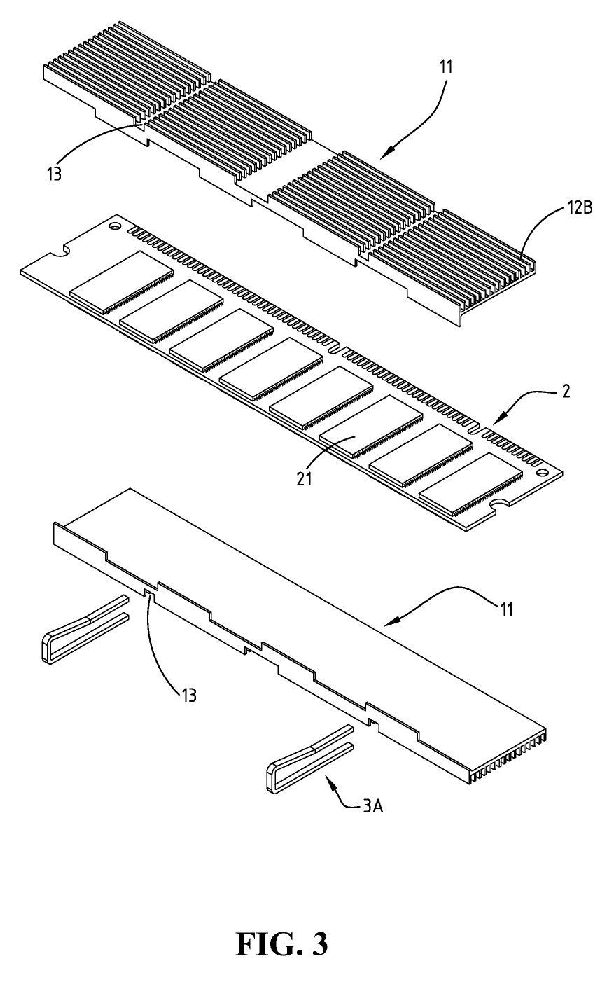

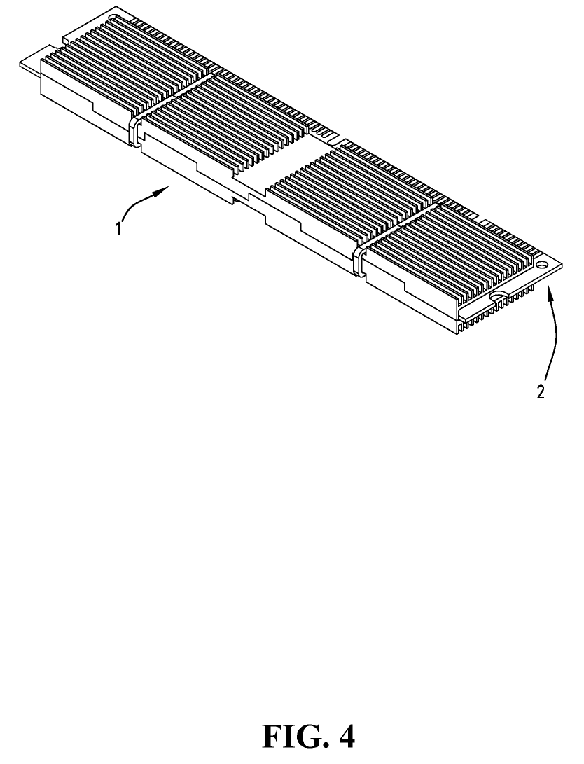

Referring to FIGS. 3 and 4, the protrusions on the heat sink 11 are a plurality of fins 12B that are parallel with the length direction (i.e. the axial direction) of the heat sink 11 according to a second embodiment of the present invention. The fixation spaces 13 separate the axial fins 12B into a plurality of partitions. The clamping members 3B according to the second embodiment are clips, which are used to hold the two heat sinks 11 at both sides of the memory 2.

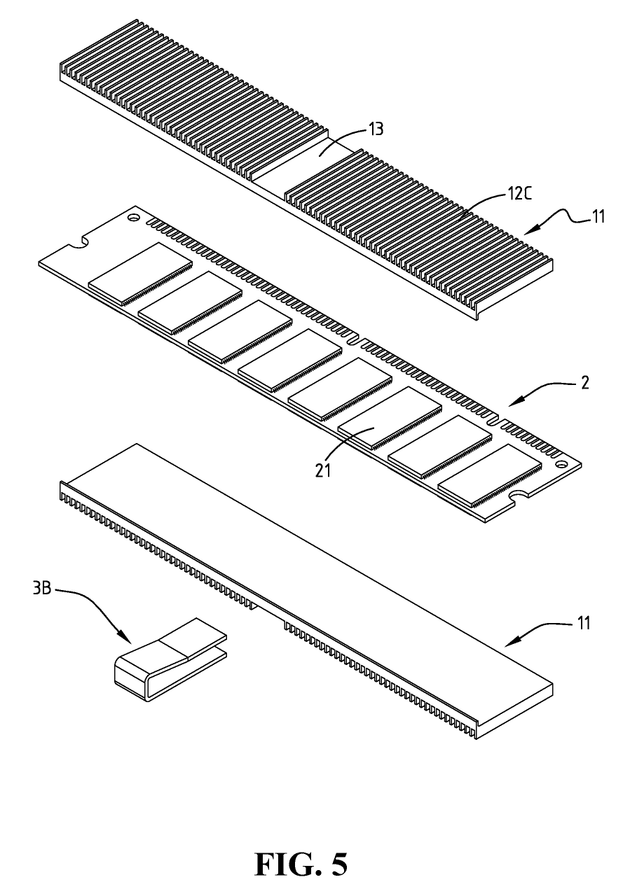

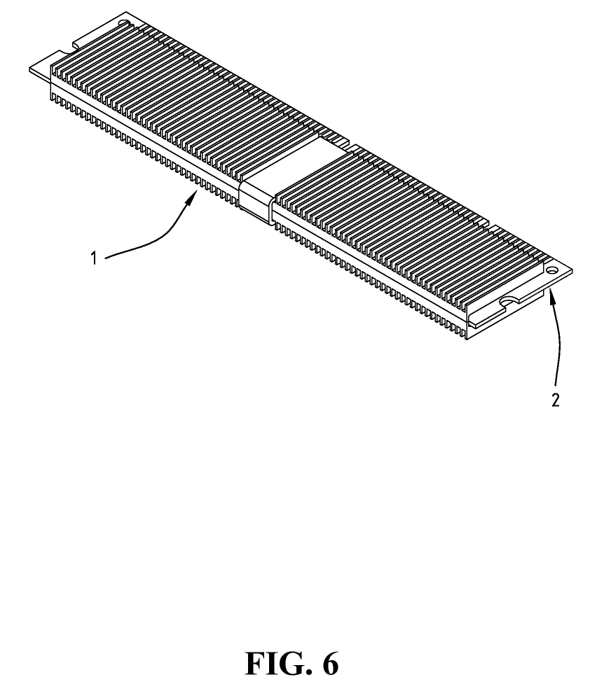

Referring to FIGS. 5 and 6, the protrusions on the heat sink 11 are a plurality of fins 12C that are perpendicular to the length direction (i.e. the lateral direction) of the heat sink 11 according to a third embodiment of the present invention. The fixation space 13 separates the lateral fins 12C into a plurality of partitions. The fixation space 13 according to the third embodiment is provided with a clip as the clamping member 3B to hold the two heat sinks 11 at both sides of the memory 2.

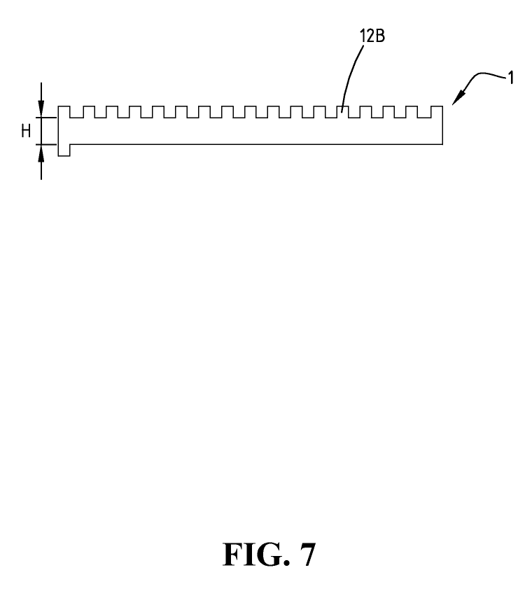

The various heat sinks 11 in accordance with the aforementioned embodiments of the present invention are integrally manufactured. Referring to FIG. 7, the heat sinks 11 are made of plates with appropriate thickness H to store heat. The heat is transferred to the protrusions and then dissipated into the surrounding environment, thereby achieving an excellent heat-dissipating effect. If heat sinks 11 are made of copper, the manufacturing process can be forging, powder metallurgy, extrusion or the like. If the heat sinks 11 are made of aluminum, the manufacturing process can be forging, casting, extrusion or the like.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method for manufacturing a heat-dissipating device for a memory, comprising the step of integrally forming a plurality of protrusions on one side of a metal plate and a flat portion on the other side of the metal plate, thus forming a heat sink.

2. The method as claimed in claim 1, wherein said protrusions are raised dots.

3. The method as claimed in claim 1, wherein said protrusions are combs.

4. The method as claimed in claim 2, wherein said metal plate is made of copper and formed by forging.

5. The method as claimed in claim 3, wherein said metal plate is made of copper and formed by forging.

6. The method as claimed in claim 2, wherein said metal plate is made of copper and formed by powder metallurgy.

7. The method as claimed in claim 3, wherein said metal plate is made of copper and formed by powder metallurgy.

8. The method as claimed in claim 2, wherein said metal plate is made of aluminum and formed by forging.

9. The method as claimed in claim 3, wherein said metal plate is made of aluminum and formed by forging.

10. The method as claimed in claim 2, wherein said metal plate is made of aluminum and formed by casting.

11. The method as claimed in claim 3, wherein said metal plate is made of aluminum and formed by casting.

12. The method as claimed in claim 1, wherein said protrusions are fins.

13. The method as claimed in claim 12, wherein said metal plate is made of copper and formed by forging.

14. The method as claimed in claim 12, wherein said metal plate is made of aluminum and formed by forging.

15. The method as claimed in claim 12, wherein said metal plate is made of copper and formed by extrusion.

16. The method as claimed in claim 12, wherein said metal plate is made of aluminum and formed by extrusion.

17. A heat-dissipating device for a memory, comprising two heat sinks, wherein each of said heat sinks is integrally manufactured with a metal plate, one side of said metal plate is provided with a plurality of protrusions, the other side of said metal plate has a flat portion, said flat portions of said two heat sinks are in contact with both sides of said memory, and a clamping member fixes said heat sinks at both sides of said memory.
